(19) United States
(12) Patent Application Publication
(10) Pub. No.: US 2026/0322378 A1
(43) Pub. Date: Oct. 15, 2026

(54) SEMICONDUCTOR DEVICE, ELECTRONIC DEVICE, AND VEHICLE

(71) Applicant: ROHM CO., LTD., Kyoto-shi (JP)

(72) Inventors: Sukenori ITO, Kyoto-shi (JP); Daiki YANAGISHIMA, Kyoto-shi (JP)

(21) Appl. No.: 19/682,559

(22) Filed: May 20, 2026

Related U.S. Application Data
(63) Continuation of application No. PCT/JP2024/040674, filed on Nov. 15, 2024.

(30) Foreign Application Priority Data
Nov. 24, 2023 (JP) 2023-199385

(51) Int. Cl. H03K 17/691; H03K 17/687

(52) U.S. Cl. CPC H03K 17/691; H03K 17/6874; H03K 2217/0063; H03K 2217/0072

(57) ABSTRACT

A semiconductor device includes, for example, at least one voltage driving circuit that voltage drives a switch control signal, and a current driving circuit that current drives the switch control signal. The at least one voltage driving circuit is in ON state during partial periods among a plurality of periods included in a logic level transition period of the switch control signal and is in OFF state during the other period. The current driving circuit is in ON state during all the plurality of periods.

### CROSS REFERENCE TO RELATED APPLICATIONS

This application is a continuation under 35 U.S.C. § 120 of PCT/JP 2024/040674, filed Nov. 15, 2024, which is incorporated herein by reference, and which claimed priority to Japanese Application No. 2023-199385, filed Nov. 24, 2023. The present application likewise claims priority under 35 U.S.C. § 119 to Japanese Application No. 2023-199385, filed Nov. 24, 2023, the entire content of which is also incorporated herein by reference.

### TECHNICAL FIELD

The present disclosure relates to a semiconductor device, an electronic device, and a vehicle.

### BACKGROUND ART

Conventionally, a signal transmission device, which transmits a signal between a primary circuit system and a secondary circuit system while insulating between the primary circuit system and the secondary circuit system, is used for various applications (such as a power supply device and a motor driving device).

Note that as an example of a conventional technique related to the above description, there is Patent Document 1 that this applicant has applied.

### LIST OF CITATIONS

### Patent Literature

Patent Document 1: WO2022/070944

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram illustrating a first comparative example of an electronic device.

FIG. 11 is a diagram illustrating a second comparative example of the, electronic device.

FIG. 12 is a diagram illustrating a first embodiment of the electronic device.

FIG. 13 is a diagram illustrating a turn-on control of the first embodiment.

FIG. 14 is a diagram illustrating a turn-on control (a variation) of the first embodiment.

FIG. 15 is a diagram illustrating a turn-off control of the first embodiment.

FIG. 16 is a diagram illustrating a second embodiment of the electronic device.

FIG. 17 is a diagram illustrating a turn-on control of the second embodiment.

FIG. 18 is a diagram illustrating a turn-off control of the second embodiment.

FIG. 19 is a diagram illustrating an external view of a vehicle.

### DESCRIPTION OF EMBODIMENTS cl Signal Transmission Device (Basic Configuration)

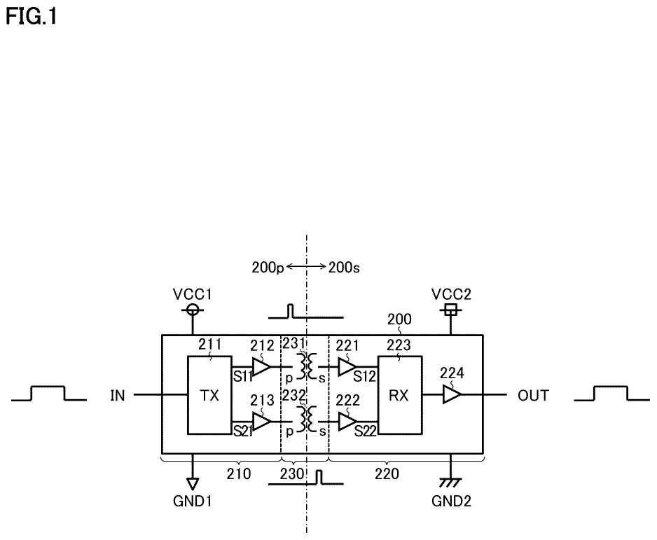

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

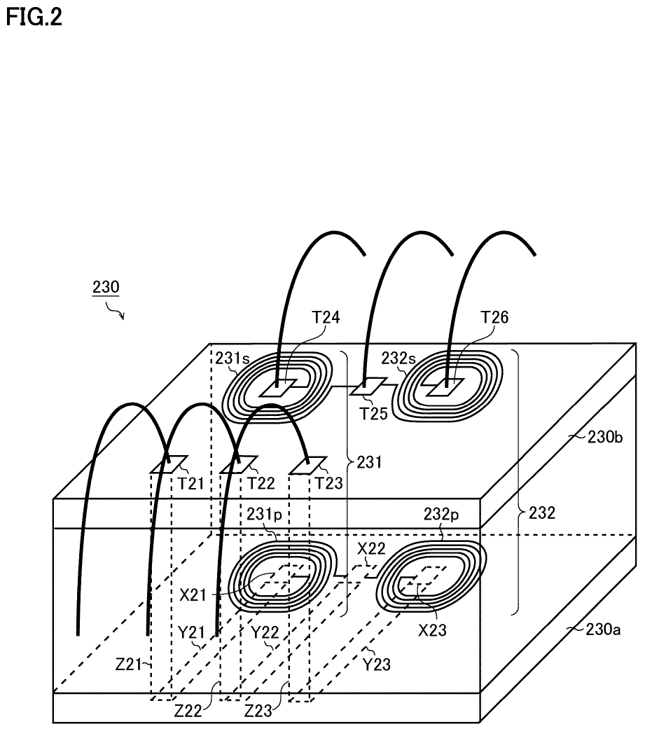

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

### Transformer Chip (Two-Channel Type)

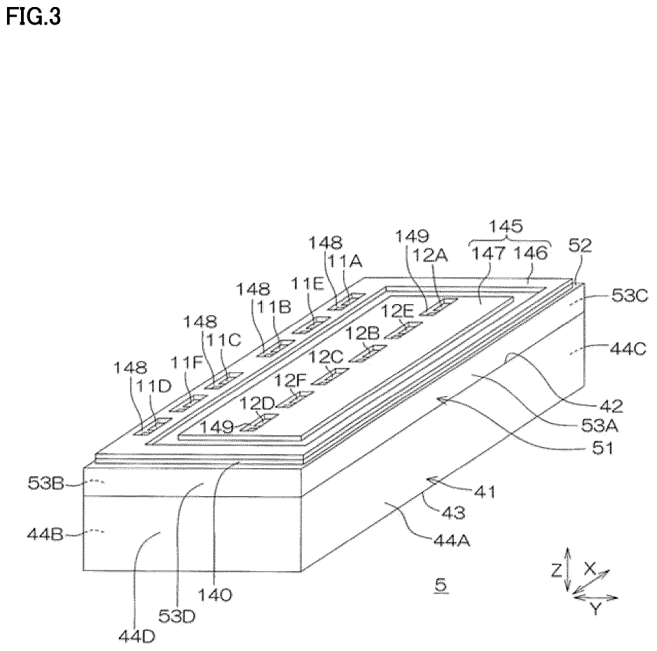

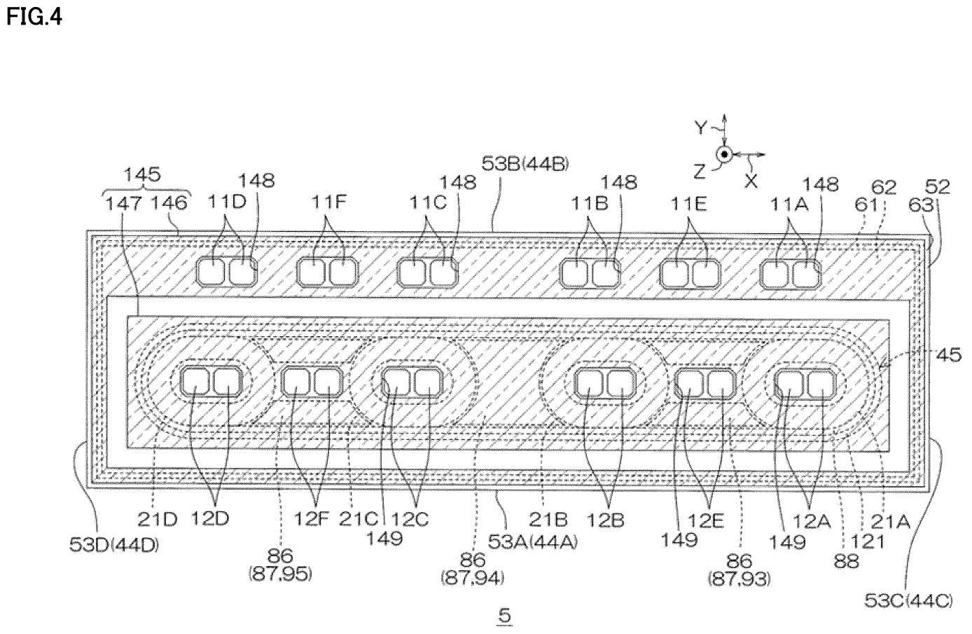

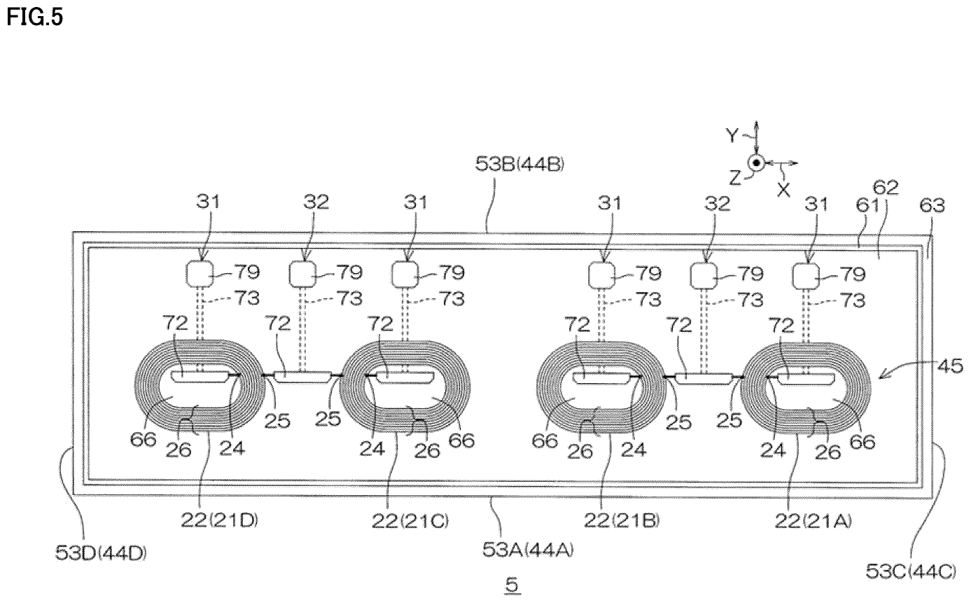

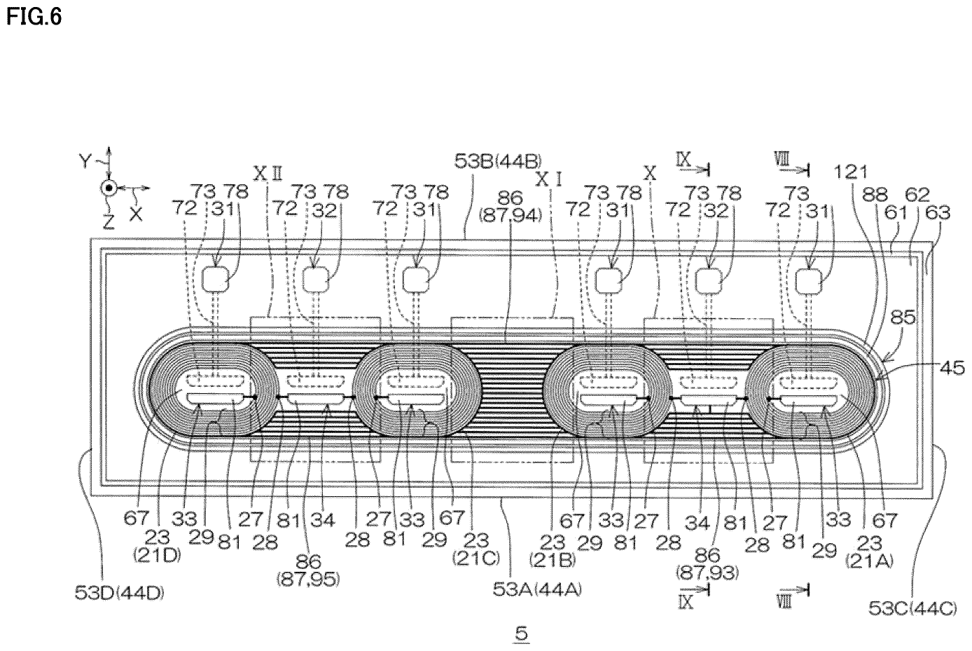

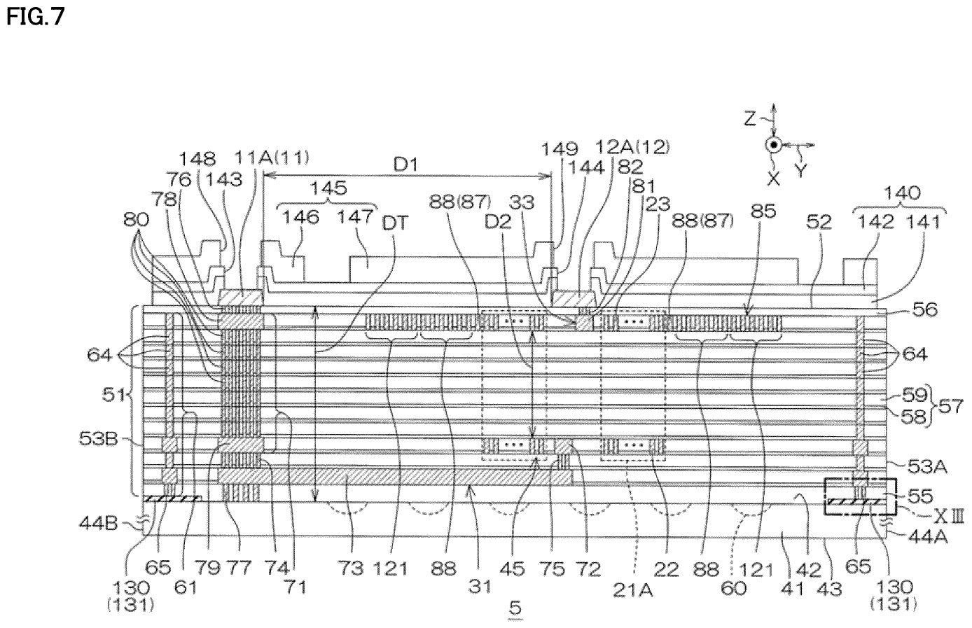

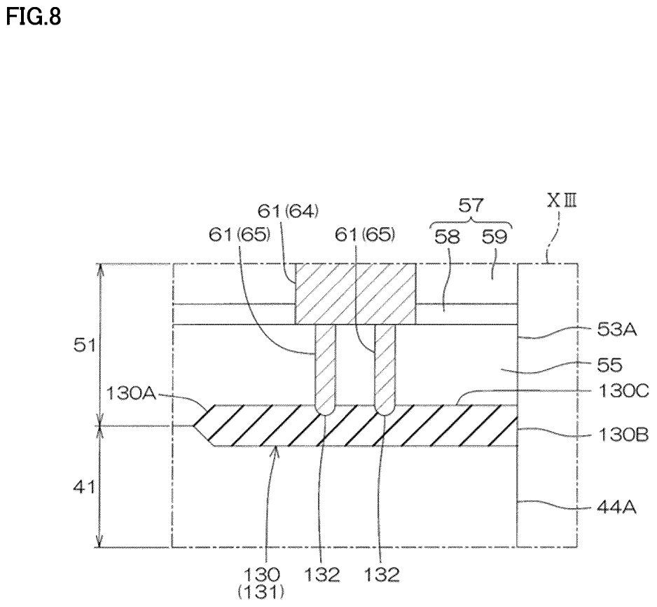

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41, and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23, and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island, and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41, and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41, and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60 however is not essential, and can be omitted.

The embodiment described above deals with an example where a dummy pattern 85 is formed. The dummy pattern 85 however is not essential, and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

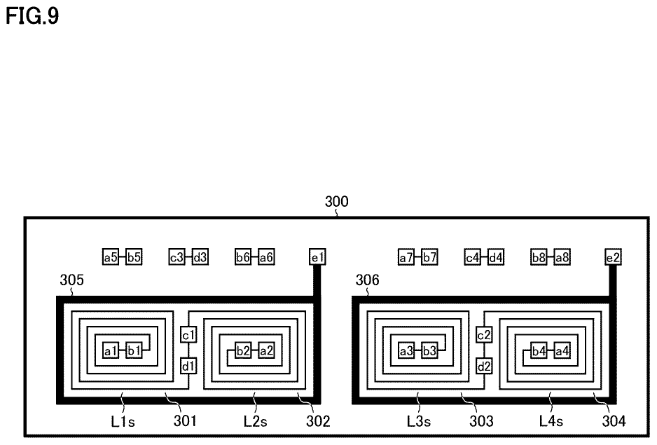

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively, and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are however not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Electronic Device (First Comparative Example)

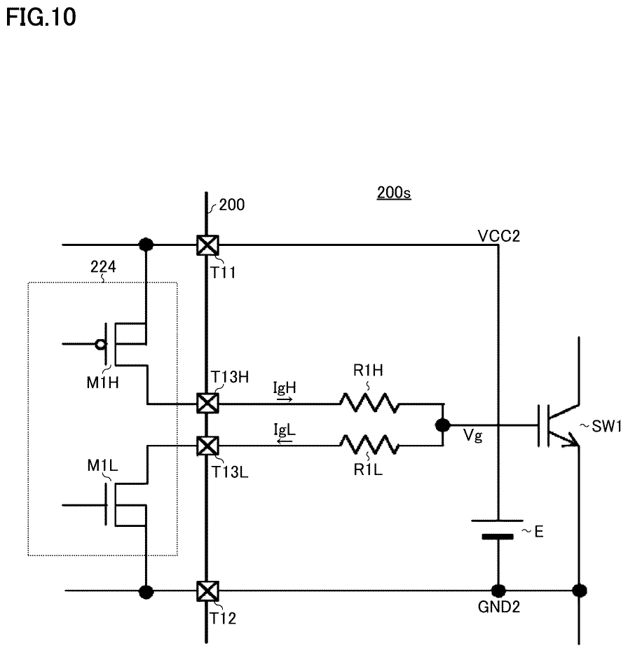

FIG. 10 is a diagram illustrating a first comparative example of an electronic device (=an example of a general circuit configuration to be compared with an embodiment described later). An electronic device A of this comparative example includes a switching element SW1, resistors R1H and R1L, a DC power supply E, and the signal transmission device 200.

As described above, the signal transmission device 200 may be a semiconductor device, which transmits a switch control signal Vg from the primary circuit system 200p to the secondary circuit system 200s, while insulating between the primary circuit system 200p and the secondary circuit system 200s (a so-called insulated gate driver IC). In this case, the switch control signal Vg corresponds to the above-mentioned output pulse signal OUT.

In addition, the signal transmission device 200 has a plurality of external terminals (external terminals T11, T12, T13H, and T13L in this diagram), as means for establishing connection with the outside of the device.

The switching element SW1 may be a power device such as an IGBT (insulated gate bipolar transistor) or the like. The gate of the switching element SW1 is connected to an application terminal of the switch control signal Vg. The emitter of the switching element SW1 is connected to an application terminal of the ground voltage GND2 in the secondary circuit system 200s. The switching element SW1 is driven by the switch control signal Vg that is applied from the signal transmission device 200 to the gate. For instance, the switching element SW1 is in ON state when the switch control signal Vg is at high level. On the other hand, the switching element SW1 is in OFF state when the switch control signal Vg is at low level.

The DC power supply E generates the power supply voltage VCC2 in the secondary circuit system 200s. A positive electrode terminal of the DC power supply E (=an application terminal of the power supply voltage VCC2) is connected to the external terminal T11 of the signal transmission device 200. A negative electrode terminal of the DC power supply E is connected to the application terminal of the ground voltage GND2, together with the external terminal T12 of the signal transmission device 200.

A first terminal of the resistor R1H is connected to the external terminal T13H of the signal transmission device 200. A first terminal of the resistor R1L is connected to the external terminal T13L of the signal transmission device 200. Second terminals of the resistors R1H and R1L are both connected to the gate of the switching element SW1 (=the application terminal of the switch control signal Vg).

In this comparative example, the driver 224 integrated in the signal transmission device 200 can be understood as a voltage driving circuit configured to voltage drive the switch control signal Vg. With reference to this diagram, the driver 224 includes a transistor M1H (e.g., a P-channel type MOSFET (metal oxide semiconductor field effect transistor)) and a transistor M1L (e.g., an N-channel type MOSFET).

Note that in this specification, a MOSFET means a transistor having a gate structure including at least three layers, i.e., a “layer made of conductor or semiconductor such as polysilicon having a small resistance”, an “isolation layer” and a “P-type, N-type, or intrinsic semiconductor layer”. In other words, the gate structure of the MOSFET is not limited to a three-layer structure of metal, oxide, and semiconductor.

The source and the backgate of the transistor M1H are both connected to the external terminal T11 (=the application terminal of the power supply voltage VCC2). The drain of the transistor M1H is connected to the external terminal T13H. The source and the backgate of the transistor M1L are both connected to the external terminal T12 (=the application terminal of the ground voltage GND2). The drain of the transistor M1L is connected to the external terminal T13L.

When the transistor M1H is in ON state while the transistor M1L is in OFF state, a gate current IgH (=source current) flows from the application terminal of the power supply voltage VCC2 through the transistor M1H and the resistor R1H to the gate of the switching element SW1. Therefore, a not-shown gate capacitor is charged, and hence the switch control signal Vg rises from low level to high level. As a result, the switching element SW1 becomes ON state.

On the other hand, when the transistor M1H is in OFF state while the transistor M1L is in ON state, a gate current IgL (=sink current) flows from the gate of the switching element SW1 through the resistor R1L and the transistor M1L to the application terminal of the ground voltage GND2. Therefore, the not-shown gate capacitor is discharged, and hence the switch control signal Vg falls from high level to low level. As a result, the switching element SW1 becomes OFF state.

### Electronic Device (Second Comparative Example)

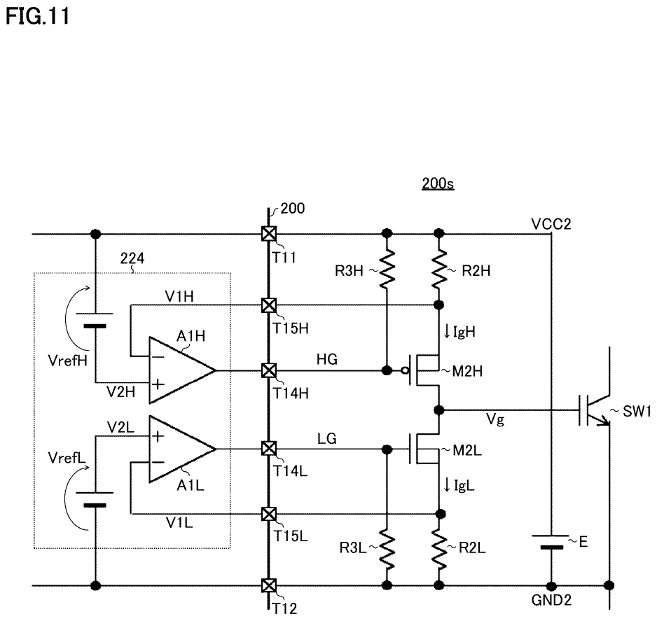

FIG. 11 is a diagram illustrating a second comparative example of the electronic device (=another example of the general circuit configuration to be compared with the embodiment described later).

The electronic device A of this comparative example includes the switching element SW1, a transistor M2H (e.g., a P-channel type MOSFET), a transistor M2L (e.g., an N-channel type MOSFET), resistors R2H and R2L, resistors R3H and R3L, the DC power supply E, and the signal transmission device 200. In addition, the signal transmission device 200 has a plurality of external terminals (external terminals T11, T12, T14H, T14L, T15H, and T15L in this diagram), as means for establishing connection with the outside of the device.

Note that the already-described components are denoted by the same numerals as in FIG. 10 described above, so as to omit overlapping descriptions, and newly appearing components will be described intensively.

First terminals of the resistors R2H and R3H are both connected to the external terminal T11 of the signal transmission device 200 (=the application terminal of the power supply voltage VCC2). A second terminal of the resistor R2H and the source and the backgate of the transistor M2H are all connected to the external terminal T15H of the signal transmission device 200 (=an application terminal of a sense voltage V1H). A second terminal of the resistor R3H and the gate of the transistor M2H are both connected to the external terminal T14H of the signal transmission device 200 (=an application terminal of a gate signal HG). The drain of the transistor M2H is connected to the gate of the switching element SW1 (=the application terminal of the switch control signal Vg).

Note that the resistor R2H works as a sense resistor for generating the sense voltage V1H (=VCC2−R2H×IgH) corresponding to the gate current IgH flowing in the transistor M2H. In addition, the resistor R3H works as a pull-up resistor for raising the gate signal HG to high level (≈power supply voltage VCC2), when the external terminal T14H is in an open state (high impedance state).

First terminals of the resistors R2L and R3L are connected to the external terminal T12 of the signal transmission device 200 (=the application terminal of the ground voltage GND2). A second terminal of the resistor R2L and the source and the backgate of the transistor M2L are all connected to the external terminal T15L of the signal transmission device 200 (=an application terminal of a sense voltage V1L). A second terminal of the resistor R3L and the gate of the transistor M2L are both connected to the external terminal T14L of the signal transmission device 200 (=an application terminal of a gate signal LG). The drain of the transistor M2L is connected to the gate of the switching element SW1 (=the application terminal of the switch control signal Vg).

Note that the resistor R2L works as a sense resistor for generating the sense voltage V1L (=GND2+R2L×IgL) corresponding to the gate current IgL flowing in the transistor M2L. In addition, the resistor R3L works as a pull-down resistor for decreasing the gate signal LG to low level (≈the ground voltage GND2), when the external terminal T14L is in the open state (high impedance state).

In this comparative example, the driver 224 integrated in the signal transmission device 200 can be understood as a current driving circuit configured to current drive the switch control signal Vg. With reference to this diagram, the driver 224 includes amplifiers A1H and A1L.

An inverting input terminal (-) of the amplifier A1H is connected to the external terminal T15H (=an application terminal of the sense voltage V1H). A noninverting input terminal (+) of the amplifier A1H is connected to an application terminal of a reference voltage V2H (=VCC2−VrefH). An output terminal of the amplifier A1H is connected to the external terminal T14H (=the application terminal of the gate signal HG).

When the amplifier A1H is in operating state, the gate signal HG is generated so that the sense voltage V1H (=VCC2−R2H×IgH) and the reference voltage V2H (=VCC2−VrefH) agree with each other. In other words, an output feedback control is performed so that the gate current IgH has the same value as a reference current value IrefH (=VrefH/R2H). On the other hand, when the amplifier A1H is in non-operating state, the external terminal T14H is in the open state (high impedance state).

An inverting input terminal (−) of the amplifier A1L is connected to the external terminal T15L (=an application terminal of the sense voltage V1L). A noninverting input terminal (+) of the amplifier A1L is connected to an application terminal of a reference voltage V2L (=GND2+VrefL). An output terminal of the amplifier A1L is connected to the external terminal T14L (=an application terminal of the gate signal LG).

When the amplifier A1L is in operating state, the gate signal LG is generated so that the sense voltage V1L (=GND2+R2L×IgL) and the reference voltage V2L (=GND2+VrefL) agree with each other. In other words, the output feedback control is performed so that the gate current IgL has the same value as a reference current value IrefL (=VrefL/R2L). On the other hand, when the amplifier A1L is in non-operating state, the external terminal T14L is in the open state (high impedance state).

When the amplifier A1H is in operating state while the amplifier A1L is in non-operating state, the gate current IgH (=source current) flows from the application terminal of the power supply voltage VCC2 through the resistor R2H and the transistor M2H to the gate of the switching element SW1. Therefore, a not-shown gate capacitor is charged, and hence the switch control signal Vg rises from low level to high level. As a result, the switching element SW1 becomes ON state.

On the other hand, when the amplifier A1H is in non-operating state while the amplifier A1L is in operating state, the gate current IgL (=sink current) flows from the gate of the switching element SW1 through the transistor M2L and the resistor R2L to the application terminal of the ground voltage GND2. Therefore, the not-shown gate capacitor is discharged, and hence the switch control signal Vg falls from high level to low level. As a result, the switching element SW1 becomes OFF state.

### Consideration About Optimization of Slew Rate

As a general method for driving a switching element such as an IGBT, an Si-MOSFET, or an SiC-MOSFET, there is a method of applying a pulse voltage between gate and source of the switching element via a gate resistor (a so-called voltage drive method), as shown in the first comparative example (FIG. 10) described above.

In this voltage drive method, by adjusting resistance of the gate resistor (e.g., the resistors R1H and R1L), a slew rate (gradient) of the switch control signal can be controlled. Note that the slew rate of the switch control signal may be understood as a variation per unit time of the gate current flowing in the switching element (di/dt), or a variation per unit time of the gate voltage applied to the switching element (dv/dt).

Here, when the slew rate of the switch control signal is decreased, an output overshoot (=transient overcurrent or overvoltage) and EMI (electro magnetic interference) noise are suppressed, but a switching loss of the switching element can be increased. On the other hand, when the slew rate of the switch control signal is increased, a switching loss of the switching element is decreased, but an output overshoot and EMI noise can be increased.

For this reason, in the voltage drive method described above, in view of the above trade-off, it is necessary to adjust resistance of the gate resistor for each switching element to be driven. However, it is not always easy to adjust resistance of the external gate resistor so as to accurately set the slew rate of the switch control signal. In addition, it has to be said that a degree of freedom in setting is also low.

On the other hand, compared with the above-mentioned voltage drive method (FIG. 10), the above-mentioned current drive method (FIG. 11) can adjust the slew rate of the switch control signal with high accuracy. However, switching speed of the gate current is rate-limited by an operation speed of an output feedback loop (such as the above-mentioned amplifiers A1H and A1L). For this reason, it is difficult to dynamically switch the gate current so as to optimize the slew rate of the switch control signal.

In view of the above consideration, a novel embodiment is proposed below, which can optimize the slew rate of the switch control signal Vg.

### Electronic Device (First Embodiment)

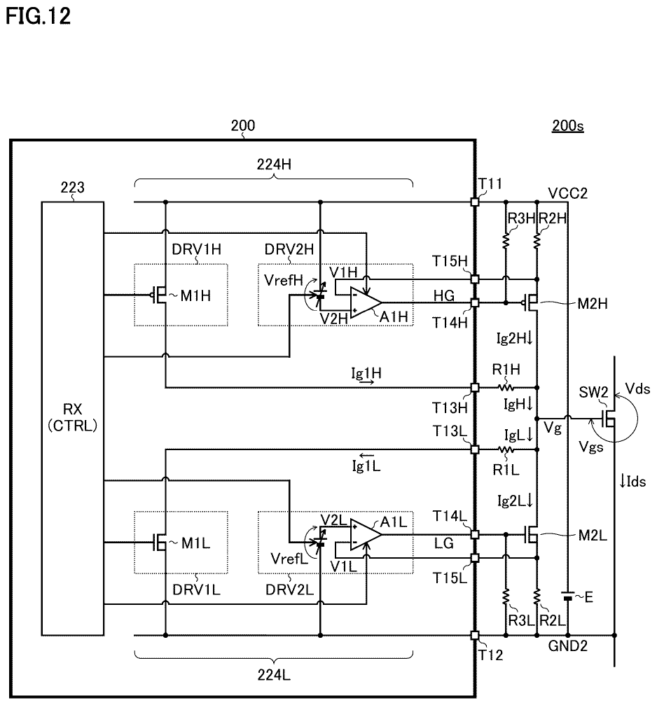

FIG. 12 is a diagram illustrating a first embodiment of an electronic device. The electronic device A of this embodiment includes a switching element SW2, the transistor M2H, the transistor M2L, the resistors R1H and R1L, the resistors R2H and R2L, the resistors R3H and R3L, the DC power supply E, and the signal transmission device 200. In addition, the signal transmission device 200 has a plurality of external terminals (the external terminals T11, T12, T13H, T13L, T14H, T14L, T15H, and T15L in this diagram), as means for establishing connection with the outside of the device. These components are disposed in the secondary circuit system 200s.

The switching element SW2 may be an N-channel type Si-MOSFET or SiC-MOSFET. The gate of the switching element SW2 is connected to the application terminal of the switch control signal Vg. The source and the backgate of the switching element SW2 are connected to the application terminal of the ground voltage GND2 in the secondary circuit system 200s. The switching element SW2 is driven by the switch control signal Vg applied from the signal transmission device 200 to the gate. For instance, the switching element SW2 becomes ON state when the switch control signal Vg is at high level. On the other hand, the switching element SW2 becomes OFF state when the switch control signal Vg is at low level. The switching element SW2 may be replaced by an IGBT (=the switching element SW1), in the same manner as the above-mentioned first comparative example (FIG. 10) and second comparative example (FIG. 11).

The signal transmission device 200 includes the above-mentioned transistors M1H and M1L, and the amplifiers A1H and A1L. The transistors M1H and M1L can be understood as voltage driving circuits DRV1H and DRV1L, respectively, which are configured to voltage drive the switch control signal Vg. In addition, the amplifiers A1H and A1L can be understood as current driving circuits DRV2H and DRV2L, respectively, which are configured to current drive the switch control signal Vg.

The voltage driving circuit DRV1H and the current driving circuit DRV2H form an upper side driver 224H. The upper side driver 224H raises the switch control signal Vg from low level to high level. The voltage driving circuit DRV1L and the current driving circuit DRV2L form a lower side driver 224L that decreases the switch control signal Vg from high level to low level.

Note that the already-described components are denoted by the same numerals as in FIG. 10 and FIG. 11 described above, so as to omit overlapping descriptions. However, for convenience sake of description, the above-mentioned gate current IgH can be understood as the sum current of a gate current Ig1H generated by the voltage driving circuit DRV1H and a gate current Ig2H generated by the current driving circuit DRV2H. In the same manner, the above-mentioned gate current IgL can be understood as the sum current of a gate current Ig1L generated by the voltage driving circuit DRV1L and a gate current Ig2L generated by the current driving circuit DRV2L.

A pulse reception circuit 223 drives the upper side driver 224H and the lower side driver 224L in accordance with the not-shown reception pulse signals S12 and S22 (see FIG. 1), so as to generate the switch control signal Vg (=output pulse signal OUT).

The pulse reception circuit 223 may have a function as a control circuit CTRL that arbitrarily adjusts the above-mentioned reference current values IrefH and IrefL. In addition, the pulse reception circuit 223 may have a function as the control circuit CTRL that arbitrarily adjusts a period during which each of the voltage driving circuits DRV1H and DRV1L is set to ON state, and a period during which each of the current driving circuits DRV2H and DRV2L is set to ON state.

Note that the control circuit CTRL may perform the above adjustment, on the basis of register setting by SPI (serial peripheral interface) communication, set data read from an internal nonvolatile memory (not shown), or an external analog input signal (such as a PWM (pulse width modulation) signal).

In addition, the control circuit CTRL may be disposed separately and independently from the pulse reception circuit 223.

In this way, the electronic device A of this embodiment can be understood as a combination of the above-mentioned first comparative example (FIG. 10) and the second comparative example (FIG. 11).

In particular, in the signal transmission device 200, the ON/OFF state of each of the voltage driving circuits DRV1H and DRV1L and the current driving circuits DRV2H and DRV2L is switched at an appropriate timing, and hence turn-on control and turn-off control are each optimized. Hereinafter, detailed description is given with reference to the drawings.

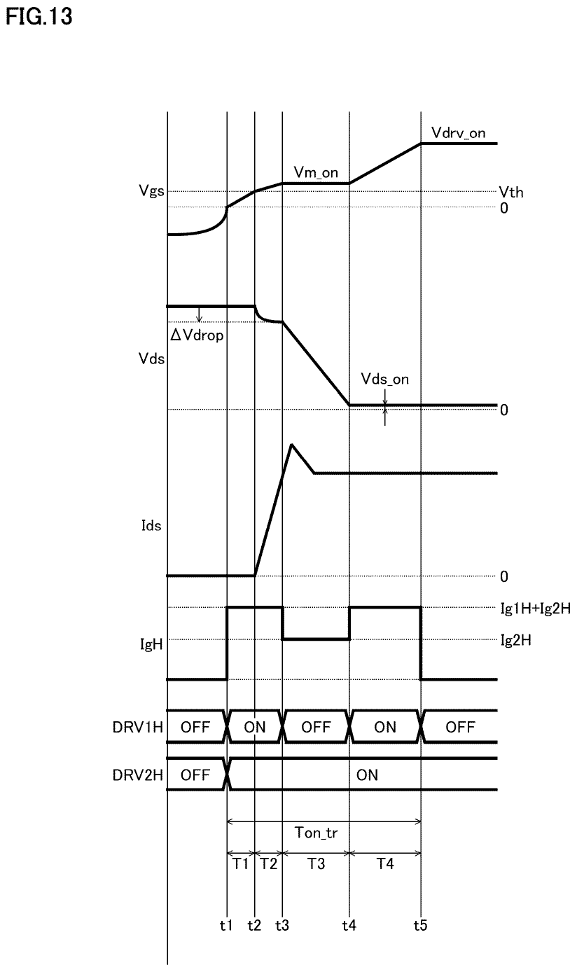

FIG. 13 is a diagram illustrating the turn-on control of the first embodiment. In this diagram, a gate-source voltage Vgs, a drain-source voltage Vds, a drain-source current Ids, and the gate current IgH of the switching element SW2, and the ON/OFF states of the voltage driving circuit DRV1H and the current driving circuit DRV2H are shown from top to bottom.

As illustrated in this diagram, when the gate-source voltage Vgs of the switching element SW2 rises from low level (=0 V) to high level (=Vdrv_on), a logic level transition period Ton_tr (=time points t1 to t5) includes four periods T1, T2, T3, and T4.

For instance, the period T1 (=time points t1 to t2) corresponds to a period from start of charging a gate parasitic capacitance of the switching element SW2, until the gate-source voltage Vgs of the switching element SW2 rises to an on threshold voltage Vth of the switching element SW2.

For instance, the period T2 (=time points t2 to t3) corresponds to a period after the gate-source voltage Vgs of the switching element SW2 exceeds the on threshold voltage Vth, until it rises to a mirror voltage Vm_on. From another perspective, the period T2 can be understood as a period during which the drain-source current Ids of the switching element SW2 increases. Note that the drain-source voltage Vds of the switching element SW2 decreases by a variation ΔVdrop during the period T2.

For instance, the period T3 (=time points t3 to t4) corresponds to a period during which the gate-source voltage Vgs of the switching element SW2 becomes constant due to a mirror effect (a so-called plateau region). Basically, during the period T3, the gate-source voltage Vgs and the drain-source current Ids of the switching element SW2 are each kept at a constant value, while only the drain-source voltage Vds of the switching element SW2 is decreased. Note that during the period T3, as illustrated in this diagram, an overshoot can occur in the drain-source current Ids of the switching element SW2.

For instance, the period T4 (=time points t4 to t5) corresponds to a period after the gate-source voltage Vgs of the switching element SW2 restarts to rise, until it becomes high level (=Vdrv_on). In this case, the drain-source voltage Vds of the switching element SW2 decreases to a voltage value Vds_on (=Ids×Ron(SW2), where Ron(SW2) is an on-resistance of the switching element SW2).

Here, the voltage driving circuit DRV1H is in ON state during the partial periods T1, T2 and T4 among the periods T1 to T4, and is in OFF state during the other period T3. On the other hand, the current driving circuit DRV2H is in ON state during all the periods T1 to T4.

In other words, during the periods T1 and T2 (=time points t1 to t3) and the period T4 (=time points t4 to t5), the voltage driving circuit DRV1H and the current driving circuit DRV2H are both in ON state. In this case, the gate current IgH has the sum current value of the gate currents Ig1H and Ig2H (IgH=Ig1H+Ig2H). Therefore, the rising slew rate of the gate-source voltage Vgs (=the switch control signal Vg) is increased.

On the other hand, during the period T3 (=time points t3 to t4), the voltage driving circuit DRV1H is in OFF state while the current driving circuit DRV2H is in ON state. In this case, only the gate current Ig2H flows as the gate current IgH. Therefore, the rising slew rate of the gate-source voltage Vgs (=the switch control signal Vg) is decreased.

In this way, by using the gate drive method suitable for each of the four periods T1 to T4, an optimal drive waveform of the switch control signal Vg can be generated. With reference to this diagram, in the turn-on control of this embodiment, the gate current IgH of the switch control signal Vg during the logic level transition period Ton_tr (and hence, the rising slew rate of the switch control signal Vg) is dynamically switched to be from “large” to “small” to “large”.

Here, the current driving circuit DRV2H is kept to be always in ON state during the periods T1 to T4. In other words, the switching control of the gate current IgH is realized by the on/off control of the voltage driving circuit DRV1H. Therefore, a problem of slow switching speed of the gate current Ig2H in the current driving circuit DRV2H can be solved. In particular, if the switching element SW2 is a power device (e.g., an SiC-MOSFET) that can be switched fast, it can be said that the gate drive control of this embodiment is suitable.

In addition, as described above, it may be possible to arbitrarily adjust parameters such as an amplitude of the reference current value IrefH (=the gate current Ig2H) and lengths (start points and end points) of the periods T1 to T4, on the basis of SPI communication, a nonvolatile memory, or an external analog input signal. For instance, by adjusting the above parameters for each switching element SW2, the rising slew rate of the switch control signal Vg can be accurately set without adjusting the external resistors R1H and R2H. Therefore, suppression of output overshoot and EMI noise, and reduction of switching loss can be both achieved.

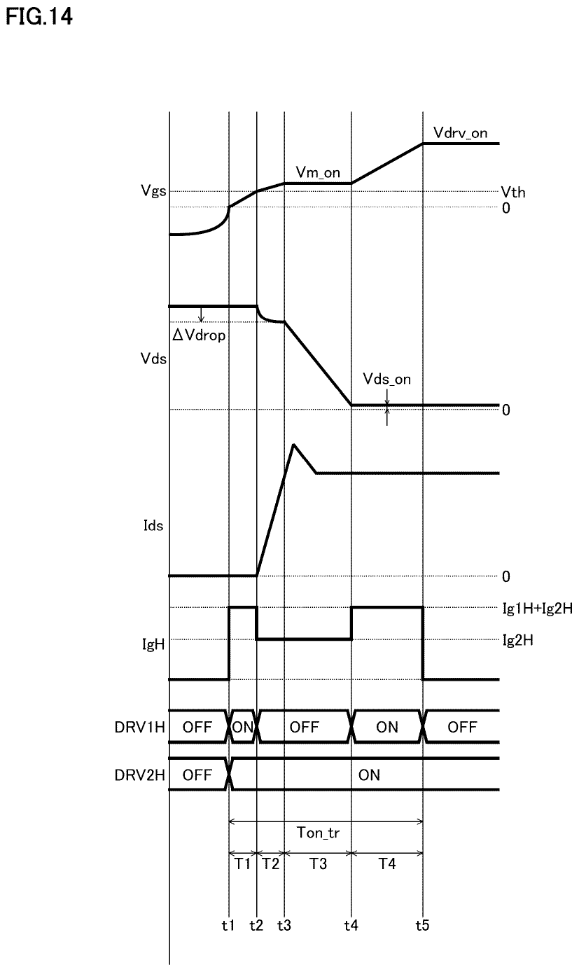

FIG. 14 is a diagram illustrating the turn-on control (variation) of the first embodiment. In the same manner as in FIG. 13 described above, in this diagram, the gate-source voltage Vgs, the drain-source voltage Vds, the drain-source current Ids, and the gate current Ig of the switching element SW2H, and the ON/OFF states of the voltage driving circuit DRV1H and the current driving circuit DRV2H are shown from top to bottom.

In this variation, in the period T1 (=time points t1 to t2) and the period T4 (=time points t4 to t5), the voltage driving circuit DRV1H and the current driving circuit DRV2H are both in ON state. In this case, the gate current IgH has the sum current value of the gate currents Ig1H and Ig2H (IgH=Ig1H+Ig2H). Therefore, the rising slew rate of the gate-source voltage Vgs (=the switch control signal Vg) is increased.

On the other hand, in the periods T2 and T3 (=time points t2 to t4), the voltage driving circuit DRV1H is in OFF state, and the current driving circuit DRV2H is in ON state. In this case, only the gate current Ig2H flows as the gate current IgH. Therefore, the rising slew rate of the gate-source voltage Vgs (=the switch control signal Vg) is decreased.

In this way, the voltage driving circuit DRV1H may be in ON state during the partial periods T1 and T4 among the periods T1 to T4 and may be in OFF state during the other periods T2 and T3. On the other hand, the current driving circuit DRV2H is in ON state during all the periods T1 to T4.

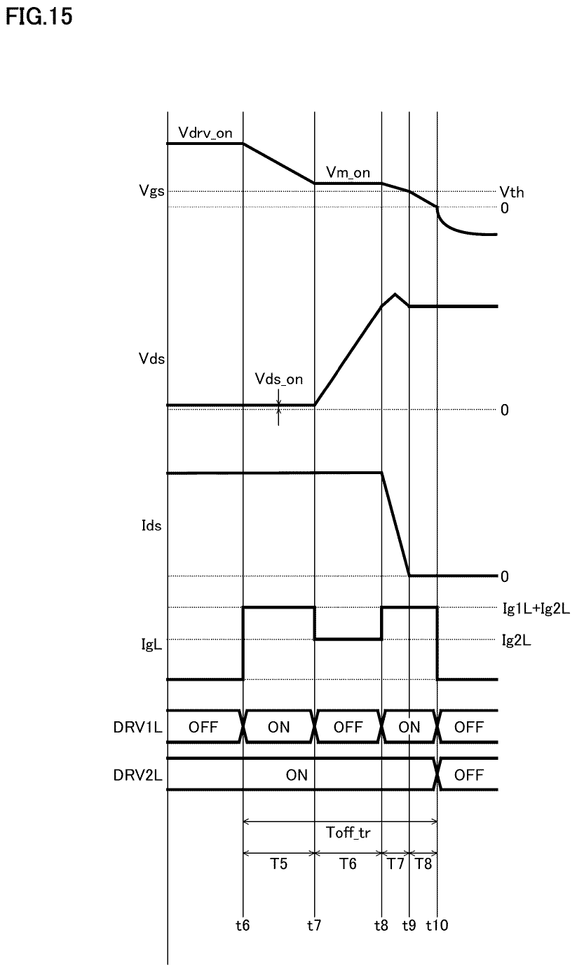

FIG. 15 is a diagram illustrating the turn-off control of the first embodiment. In this diagram, the gate-source voltage Vgs, the drain-source voltage Vds, the drain-source current Ids, and the gate current IgL of the switching element SW2, and the ON/OFF states of the voltage driving circuit DRV1L and the current driving circuit DRV2L are shown from top to bottom.

As illustrated in this diagram, a logic level transition period Toff_tr (=time points t6 to t10), when the gate-source voltage Vgs of the switching element SW2 falls from high level (=Vdrv_on) to low level (=0 V), includes four periods T5, T6, T7, and T8.

For instance, the period T5 (=time points t6 to t7) corresponds to a period from start of discharging a gate parasitic capacitance of the switching element SW2, until decreasing to the mirror voltage Vm_on. In this case, the drain-source voltage Vds of the switching element SW2 is kept at the voltage value Vds_on (=Ids×Ron(SW2)).

For instance, the period T6 (=time points t7 to t8) corresponds to a period during which the gate-source voltage Vgs of the switching element SW2 becomes constant due to a mirror effect (a so-called plateau region). Basically, during the period T6, the gate-source voltage Vgs and the drain-source current Ids of the switching element SW2 are each kept at a constant value, while only the drain-source voltage Vds of the switching element SW2 is increased.

For instance, the period T7 (=time points t8 to t9) corresponds to a period after the gate-source voltage Vgs of the switching element SW2 restarts to decrease, until it becomes the on threshold voltage Vth of the switching element SW2. From another perspective, the period T7 can be understood as a period of decreasing the drain-source current Ids of the switching element SW2. Note that an overshoot can occur on the drain-source voltage Vds of the switching element SW2 during the period T7.

For instance, the period T8 (=time points t9 to t10) corresponds to a period after the gate-source voltage Vgs of the switching element SW2 becomes lower than the on threshold voltage Vth, until it becomes low level (=0 V).

Here, the voltage driving circuit DRV1L is in ON state during the partial periods T5, T7, and T8 among the periods T5 to T8, and is in OFF state during the other period T6. On the other hand, the current driving circuit DRV2L is in ON state during all the periods T5 to T8.

In other words, the voltage driving circuit DRV1L and the current driving circuit DRV2L are both in ON state during the period T5 (=time points t6 to t7) and the periods T7 and T8 (=time points t8 to t10). In this case, the gate current IgL has the sum current value of the gate currents Ig1L and Ig2L (IgL=Ig1L+Ig2L). Therefore, the falling slew rate of the gate-source voltage Vgs (=the switch control signal Vg) is increased.

On the other hand, during the period T6 (=time points t7 to t8), the voltage driving circuit DRV1L is in OFF state while the current driving circuit DRV2L is in ON state. In this case, only the gate current Ig2L flows as the gate current IgL. Therefore, the falling slew rate of the gate-source voltage Vgs (=the switch control signal Vg) is decreased.

In this way, by using the gate drive method suitable for each of the four periods T5 to T8, an optimal drive waveform of the switch control signal Vg can be generated. With reference to this diagram, in the turn-on control of this embodiment, the gate current IgL of the switch control signal Vg during the logic level transition period Toff_tr (and hence, the falling slew rate of the switch control signal Vg) is dynamically switched from “large” to “small” to “large”.

Here, the current driving circuit DRV2L is kept to be always in ON state during the periods T5 to T8. In other words, the switching control of the gate current IgL is realized by the on/off control of the voltage driving circuit DRV1L. Therefore, a problem of slow switching speed of the gate current Ig2L in the current driving circuit DRV2L can be solved. In particular, if the switching element SW2 is a power device (e.g., an SiC-MOSFET) that can be switched fast, it can be said that the gate drive control of this embodiment is suitable.

In addition, as described above, it may be possible to arbitrarily adjust parameters such as an amplitude of the reference current value IrefL (=the gate current Ig2L) and lengths (start points and end points) of the periods T5 to T8, on the basis of SPI communication, a nonvolatile memory, or an external analog input signal. For instance, by adjusting the above parameters for each switching element SW2, the falling slew rate of the switch control signal Vg can be accurately set without adjusting the external resistors R1L and R2L. Therefore, suppression of output overshoot and EMI noise, and reduction of switching loss can be both achieved.

Note that although not illustrated again, in the same manner as the variation of the turn-on control described above (FIG. 14), the voltage driving circuit DRV1L may be in ON state during the partial periods T5 and T8 among the periods T5 to T8, and may be in OFF state during the other periods T6 and T7. On the other hand, the current driving circuit DRV2L is in ON state during all the periods T5 to T8.

### Electronic Device (Second Embodiment)

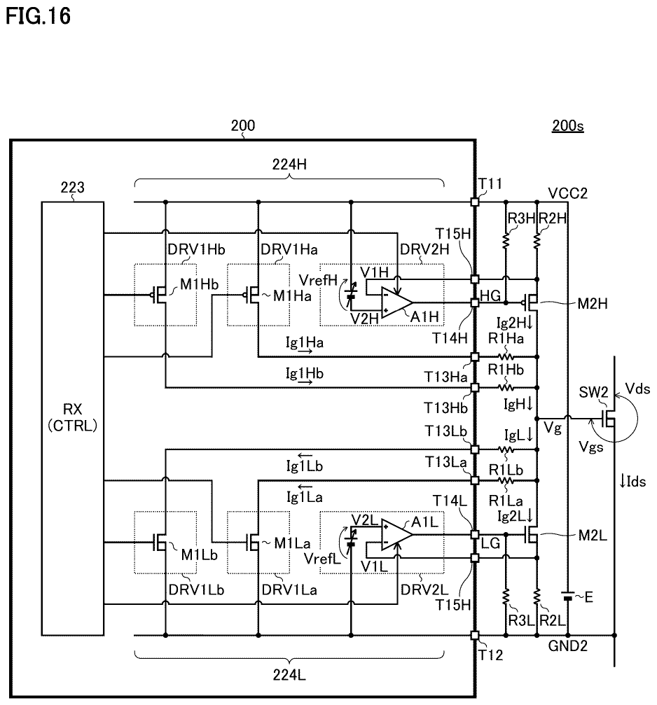

FIG. 16 is a diagram illustrating a second embodiment of the electronic device. In the electronic device A of this embodiment, while based on the above-mentioned first embodiment (FIG. 12), modifications are added to the configuration of the signal transmission device 200 and external elements.

With reference to this diagram, the signal transmission device 200 includes transistors M1Ha and M1Hb (e.g., a P-channel type MOSFET each) instead of the transistor M1H. In addition, the signal transmission device 200 external terminals T13Ha and T13Hb instead of the external terminal T13H.

The source and the backgate of the transistor M1Ha are both connected to the external terminal T11. The drain of the transistor M1Ha is connected to the external terminal T13Ha. A resistor R1Ha is externally connected between the external terminal T13Ha and the gate of the switching element SW2. The transistor M1Ha connected as described above can be understood as a voltage driving circuit DRV1Ha configured to voltage drive the switch control signal Vg via the resistor R1Ha.

The source and the backgate of the transistor M1Hb are both connected to the external terminal T11. The drain of the transistor M1Hb is connected to the external terminal T13Hb. A resistor R1Hb is externally connected between the external terminal T13Hb and the gate of the switching element SW2. The transistor M1Hb connected as described above can be understood as a voltage driving circuit DRV1Hb configured to voltage drive the switch control signal Vg via the resistor R1Hb that is different from the resistor R1Ha.

Note that the above-mentioned gate current Ig1H is divided into two systems, i.e., a gate current Ig1Ha flowing in the transistor M1Ha and a gate current Ig1Hb flowing in the transistor M1Hb.

In addition, the signal transmission device 200 includes transistors M1La and M1Lb (e.g., an N-channel type MOSFET each) instead of the transistor M1L. In addition, the signal transmission device 200 includes external terminals T13La and T13Lb instead of the external terminal T13L.

The source and the backgate of the transistor M1La are both connected to the external terminal T12. The drain of the transistor M1La is connected to the external terminal T13La. A resistor R1La is externally connected between the external terminal T13La and the gate of the switching element SW2. The transistor M1La connected as described above can be understood as a voltage driving circuit DRV1La configured to voltage drive the switch control signal Vg via the resistor R1La.

The source and the backgate of the transistor M1Lb are both connected to the external terminal T12. The drain of the transistor M1Lb is connected to the external terminal T13Lb. A resistor R1Lb is externally connected between the external terminal T13Lb and the gate of the switching element SW2. The transistor M1Lb connected a described above can be understood as a voltage driving circuit DRV1Lb configured to voltage drive the switch control signal Vg via the resistor R1Lb that is different from the resistor R1La.

Note that the above-mentioned the gate current Ig1L is divided into two systems, i.e., a gate current Ig1La flowing in the transistor M1La and a gate current Ig1Lb flowing in the transistor M1Lb.

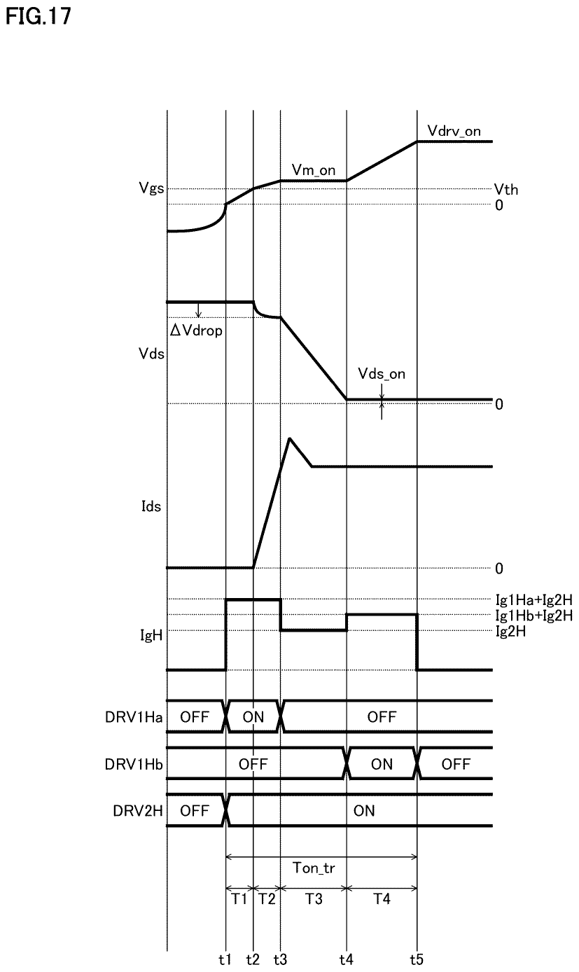

FIG. 17 is a diagram illustrating the turn-on control of the second embodiment. In this diagram, the gate-source voltage Vgs, the drain-source voltage Vds, the drain-source current Ids, and the gate current IgH of the switching element SW2, and the ON/OFF states of the voltage driving circuits DRV1Ha and DRV1Hb, and the current driving circuit DRV2H are shown from top to bottom.

Here, points different from the turn-on control of the first embodiment (FIG. 13) are described. With reference to this diagram, the voltage driving circuit DRV1Ha is in ON state during the partial periods T1 and T2 among the periods T1 to T4, and it is in OFF state during the other periods T3 and T4. In addition, the voltage driving circuit DRV1Hb is in ON state during the partial period T4 among the periods T1 to T4, and is in OFF state during the other periods T1 to T3. On the other hand, the current driving circuit DRV2H is in ON state during all the periods T1 to T4.

In other words, during the periods T1 and T2 (=time points t1 to t3), the voltage driving circuit DRV1Ha and the current driving circuit DRV2H are in ON state, and the voltage driving circuit DRV1Hb is in OFF state. In this case, the gate current IgH has the sum current value of the gate currents Ig1Ha and Ig2H (IgH=Ig1Ha+Ig2H). Therefore, the rising slew rate of the gate-source voltage Vgs (=the switch control signal Vg) is set to a setting value RSR1.

On the other hand, during the period T3 (=time points t3 to t4), the voltage driving circuits DRV1Ha and DRV1Hb are both in OFF state, and the current driving circuit DRV2H is in ON state. In this case, only the gate current Ig2H flows as the gate current IgH. Therefore, the rising slew rate of the gate-source voltage Vgs (=the switch control signal Vg) is decreased from the setting value RSR1 to a setting value RSR2.

During the period T4 (=time points t4 to t5), the voltage driving circuit DRV1Hb and the current driving circuit DRV2H are in ON state, and the voltage driving circuit DRV1Ha is in OFF state. In this case, the gate current IgH has the sum current value of the gate currents Ig1Hb and Ig2H (IgH=Ig1Hb+Ig2H). Therefore, the rising slew rate of the gate-source voltage Vgs (=the switch control signal Vg) is increased from the setting value RSR2 to the setting value RSR3 (≠RSR1 is possible).

In this way, when the plurality of voltage driving circuits DRV1Ha and DRV1Hb are disposed, the drive waveform of the switch control signal Vg can be optimized finely compared with the first embodiment described above (FIG. 12). Furthermore, it is the same that the gate current IgH of the switch control signal Vg during the logic level transition period Ton_tr (and hence, the rising slew rate of the switch control signal Vg) is dynamically switched from “large” to “small” to “large”.

Note that although not illustrated again, in the same manner as the variation of the turn-on control described above (FIG. 14), the voltage driving circuit DRV1Ha may be in ON state during the partial period T1 among the periods T1 to T4 and may be in OFF state during the other periods T2 to T4.

In addition, an example where Ig1Ha>Ig1Hb holds is illustrated in this diagram, but oppositely, it may be possible that Ig1Ha<Ig1Hb holds.

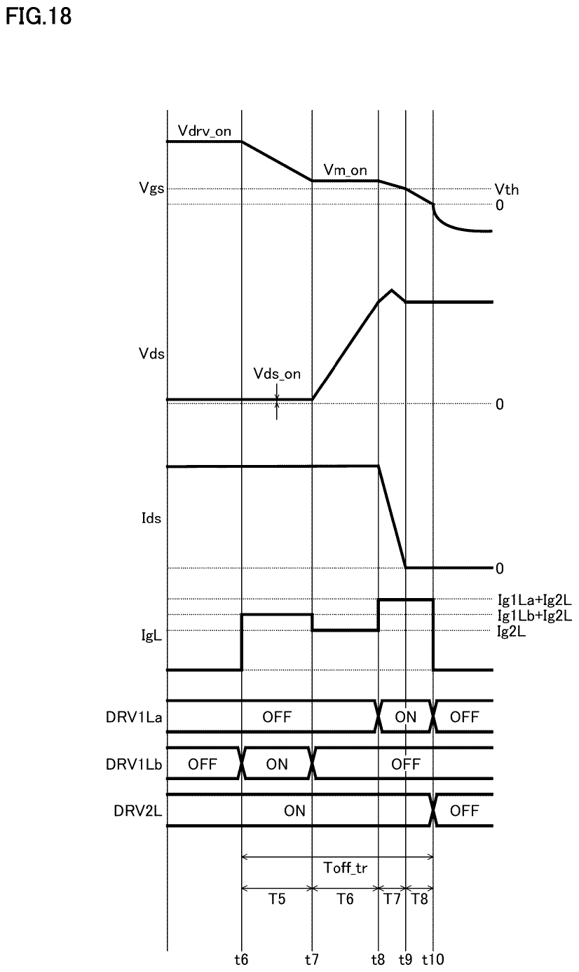

FIG. 18 is a diagram illustrating the turn-off control of the second embodiment. In this diagram, the gate-source voltage Vgs, the drain-source voltage Vds, the drain-source current Ids, and the gate current IgH of the switching element SW2, and the ON/OFF states of the voltage driving circuits DRV1La and DRV1Lb, and the current driving circuit DRV2H are shown from top to bottom.

Here, points different from the turn-off control of the first embodiment (FIG. 15) are described. With reference to this diagram, the voltage driving circuit DRV1La is in ON state during the partial periods T7 and T8 among the periods T5 to T8, and it is in OFF state during the other periods T5 and T6. In addition, the voltage driving circuit DRV1Lb is in ON state during the partial period T5 among the periods T5 to T8 and is in OFF state during the other periods T6 to T8. On the other hand, the current driving circuit DRV2L is in ON state during all the periods T5 to T8.

In other words, during the period T5 (=time points t6 to t7), the voltage driving circuit DRV1Lb and the current driving circuit DRV2L are in ON state, and the voltage driving circuit DRV1La is in OFF state. In this case, the gate current IgL is the sum current value of the gate currents Ig1Lb and Ig2L (IgL=Ig1Lb+Ig2L). Therefore, the falling slew rate of the gate-source voltage Vgs (=the switch control signal Vg) is set to a setting value FSR1.

On the other hand, during the period T6 (=time points t7 to t8), the voltage driving circuits DRV1La and DRV1Lb are both in OFF state, and the current driving circuit DRV2L is in ON state. In this case, only the gate current Ig2L flows as the gate current IgL. Therefore, the falling slew rate of the gate-source voltage Vgs (=the switch control signal Vg) is decreased from the setting value FSR1 to a setting value FSR2.

During the periods T7 and T8 (=time points t8 to t10), the voltage driving circuit DRV1La and the current driving circuit DRV2L are in ON state, and the voltage driving circuit DRV1Lb is in OFF state. In this case, the gate current IgL is the sum current value of the gate currents Ig1La and Ig2L (IgL=Ig1La+Ig2L). Therefore, the falling slew rate of the gate-source voltage Vgs (=the switch control signal Vg) is increased from the setting value FSR2 to a setting value FSR3 (≠FSR1 is possible).

In this way, when the plurality of voltage driving circuits DRV1La and DRV1Lb are disposed, the drive waveform of the switch control signal Vg can be optimized finely compared with the first embodiment (FIG. 12) described above. Furthermore, it is the same that the gate current IgL of the switch control signal Vg during the logic level transition period Toff_tr (and hence, the falling slew rate of the switch control signal Vg) is dynamically switched from “large” to “small” to “large”.

Note that although not illustrated again, in the same manner as the variation of the turn-on control described above (FIG. 14), the voltage driving circuit DRV1La may be in ON state during the partial period T8 among the periods T5 to T8 and may be in OFF state during the other the periods T5 to T7.

In addition, in this diagram, an example where Ig 1La>Ig1Lb holds is illustrated in this diagram, but oppositely, it may be possible that Ig1La<Ig1Lb holds.

### Application to Vehicle

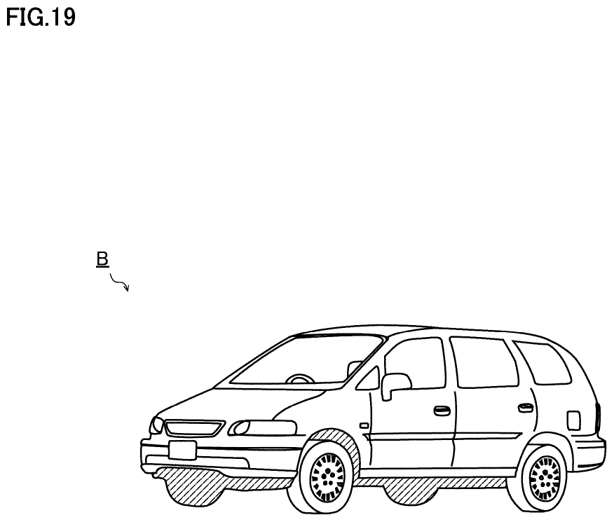

FIG. 19 is a diagram illustrating an external view of a vehicle. A vehicle B of this configuration example is equipped with various electronic devices that are supplied with electric power from a battery so as to operate.

The vehicle B includes, in addition to an engine vehicle, an electric vehicle (an xEV such as a BEV (battery electric vehicle), a HEV (hybrid electric vehicle), a PHEV/PHV (plug-in hybrid electric vehicle/plug-in hybrid vehicle), or an FCEV/FCV (fuel cell electric vehicle/fuel cell vehicle)).

Note that the signal transmission device 200 described above can be incorporated in any one of the electronic devices built in the vehicle B.

### Additional Notes

According to the present disclosure, the slew rate of the switch control signal can be optimized. Hereinafter, additional notes about the present disclosure are given.

### Additional Note 1

A semiconductor device (200) comprising:
at least one voltage driving circuit (DRV1H, DRV1Ha, DRV1Hb, DRV1L, DRV1La, DRV1Lb) configured to voltage drive a switch control signal (Vg); and
a current driving circuit (DRV2H, DRV2L) configured to current drive the switch control signal (Vg), wherein
the at least one voltage driving circuit (DRV1H, DRV1L) is in ON state during a partial period (T1, T2, T4, T5, T7, T8) among a plurality of periods (T1 to T4, T5 to T8) included in a logic level transition period (Ton_tr, Toff_tr) of the switch control signal (Vg), and is in OFF state in the other period (e.g., T3, T6), and the current driving circuit (DRV2H, DRV2L) is in ON state during all the plurality of periods (T1 to T4, T5 to T8).

### Additional Note 2

The semiconductor device (200) according to Additional Note 1, wherein
the at least one voltage driving circuit (DRV1Ha, DRV1Hb, DRV1La, DRV1Lb) includes a first voltage driving circuit (DRV1Ha, DRV1La) configured to be connected to an application terminal of the switch control signal (Vg) via a first resistor (R1Ha, R1La), and a second voltage driving circuit (DRV1Hb, DRV1Lb) configured to be connected to the application terminal of the switch control signal (Vg) via a second resistor (R1Hb, R1Lb) that is different from the first resistor (R1Ha, R1La), and
the logic level transition period (Ton_tr, Toff_tr) includes a first period (e.g., T1+T2, T7+T8) during which the first voltage driving circuit (DRV1Ha, DRV1La) and the current driving circuit (DRV2H, DRV2L) are in ON state while the second voltage driving circuit (DRV1Hb, DRV1Lb) is in OFF state, a second period (T3, T6) during which the current driving circuit (DRV2H, DRV2L) is in ON state while the first voltage driving circuit (DRV1Ha, DRV1La) and the second voltage driving circuit (DRV1Hb, DRV1Lb) are in OFF state, and a third period (T4, T5) during which the second voltage driving circuit (DRV1Hb, DRV1Lb) and the current driving circuit (DRV2H, DRV2L) are in ON state while the first voltage driving circuit (DRV1Ha, DRV1La) is in OFF state.

### Additional Note 3

The semiconductor device (200) according to Additional Note 1 or 2, wherein the current driving circuit (DRV2H, DRV2L) performs an output feedback control so that a current (Ig2H, Ig2L) flowing in the application terminal of the switch control signal (Vg) has the same value as a reference current value (IrefH, IrefL).

### Additional Note 4

The semiconductor device (200) according to Additional Note 3, further comprising a control circuit (223, CTRL) configured to arbitrarily adjust the reference current value (IrefH, IrefL).

### Additional Note 5

The semiconductor device (200) according to any one of Additional Notes 1 to 4, further comprising a control circuit (223, CTRL) configured to arbitrarily adjust the period during which each of the at least one voltage driving circuit (DRV1H, DRV1Ha, DRV1Hb, DRV1L, DRV1La, DRV1Lb) and the current driving circuit (DRV2H, DRV2L) is in ON state.

### Additional Note 6

The semiconductor device (200) according to any one of Additional Notes 1 to 5,wherein the at least one voltage driving circuit (DRV1H, DRV1Ha, DRV1Hb, DRV1L, DRV1La, DRV1Lb) and the current driving circuit (DRV2H, DRV2L) form at least one of an upper side driver (224H) configured to raise the switch control signal (Vg) from low level to high level, and a lower side driver (224L) configured to decrease the switch control signal (Vg) from high level to low level.

### Additional Note 7

The semiconductor device (200) according to any one of Additional Notes 1 to 6,wherein
the semiconductor device (200) is a signal transmission device configured to transmit the switch control signal (Vg) from a primary circuit system (200p) to a secondary circuit system (200s), while insulating between the primary circuit system (200p) and the secondary circuit system (200s), and
the at least one voltage driving circuit (DRV1H, DRV1Ha, DRV1Hb, DRV1L, DRV1La, DRV1Lb) and the current driving circuit (DRV2H, DRV2L) are each disposed in the secondary circuit system (200s).

### Additional Note 8

An electronic device (A) comprising:
the semiconductor device (200) according to any one of Additional Notes 1 to 7; and
a switching element (SW1, SW2) configured to be driven by the semiconductor device (200).

### Additional Note 9

The electronic device (A) according to Additional Note 8, wherein the switching element (SW1, SW2) is an IGBT, an Si-MOSFET, or an SiC-MOSFET.

### Additional Note 10

A vehicle (B) equipped with the electronic device (A) according to Additional Note 8 or 9.

### Others

Note that the various technical features disclosed in this specification can be variously modified within the scope of the technical invention without deviating from the spirit thereof, other than the embodiments described above. In other words, the embodiments are merely examples in every aspect and should not be interpreted as a limitation. In addition, the technical scope of the present disclosure should be defined by the claims and should be understood to include all modifications within meaning and scope equivalent to the claims.

1. A semiconductor device comprising:
at least one voltage driving circuit configured to voltage drive a switch control signal; and
a current driving circuit configured to current drive the switch control signal, wherein
the at least one voltage driving circuit is in ON state during a partial period among a plurality of periods included in a logic level transition period of the switch control signal, and is in OFF state during the other period, and
the current driving circuit is in ON state during all the plurality of periods.

2. The semiconductor device according to claim 1, wherein
the at least one voltage driving circuit includes a first voltage driving circuit configured to be connected to an application terminal of the switch control signal via a first resistor, and a second voltage driving circuit configured to be connected to the application terminal of the switch control signal via a second resistor that is different from the first resistor, and
the logic level transition period includes a first period during which the first voltage driving circuit and the current driving circuit are in ON state while the second voltage driving circuit is in OFF state, a second period during which the current driving circuit is in ON state while the first voltage driving circuit and the second voltage driving circuit are in OFF state, and a third period during which the second voltage driving circuit and the current driving circuit are in ON state while the first voltage driving circuit is in OFF state.

3. The semiconductor device according to claim 1, wherein the current driving circuit performs an output feedback control so that a current flowing in the application terminal of the switch control signal has the same value as a reference current value.

4. The semiconductor device according to claim 3, further comprising a control circuit configured to arbitrarily adjust the reference current value.

5. The semiconductor device according to claim 1, further comprising a control circuit configured to arbitrarily adjust the period during which each of the at least one voltage driving circuit and the current driving circuit is in ON state.

6. The semiconductor device according to claim 1, wherein
the at least one voltage driving circuit and the current driving circuit form at least one of an upper side driver configured to raise the switch control signal from low level to high level, and a lower side driver configured to decrease the switch control signal from high level to low level.

7. The semiconductor device according to claim 1, wherein
the semiconductor device is a signal transmission device configured to transmit the switch control signal from a primary circuit system to a secondary circuit system, while insulating between the primary circuit system and the secondary circuit system, and
the at least one voltage driving circuit and the current driving circuit are each disposed in the secondary circuit system.

8. An electronic device comprising:
the semiconductor device according to claim 1; and
a switching element configured to be driven by the semiconductor device.

9. The electronic device according to claim 8, wherein the switching element is an IGBT, an Si-MOSFET, or an SiC-MOSFET.

10. A vehicle equipped with the electronic device according to claim 8.
